(19) United States
(12) Patent Application Publication
(10) Pub. No.: US 2009/0191711 A1
(43) Pub. Date: Jul. 30, 2009

(54) HARDMASK OPEN PROCESS WITH ENHANCED CD SPACE SHRINK AND REDUCTION

(76) Inventors: Ying Rui, Santa Clara, CA (US); Nancy Fung, Livermore, CA (US); Xiaoye Zhao, Mountain View, CA (US); Kevin Mikio Mukai, Campbell, CA (US); Yasunobu Iwamoto, Kanagawa (JP)

Correspondence Address: PATTERSON & SHERIDAN, LLP - - APPM/TX, 3040 POST OAK BOULEVARD, SUITE 1500, HOUSTON, TX, 77056, US

(21) Appl. No.: 12/022,496

(22) Filed: Jan. 30, 2008

(51) Int. Cl. H01L 21/306; C23F 1/08

(52) U.S. Cl. 438/695; 438/694; 438/703; 156/345.24; 257/E21.219

(57) ABSTRACT

Methods for forming an ultra thin structure. The method includes a polymer deposition and etching process. In one embodiment, the methods may be utilized to form fabricate submicron structure having a critical dimension less than 30 nm and beyond. The method further includes a multiple etching processes. The processes may be varied to meet different process requirements. In one embodiment, the process gently etches the substrate while shrinking critical dimension of the structures formed within the substrate. The dimension of the structures may be shank by coating a photoresist like polymer to sidewalls of the formed structure, but substantially no polymer accumulation on the bottom surface of the formed structure on the substrate. The embodiments described herein also provide high selectivity in between each layers formed on the substrate during the fabricating process and preserving a good control of profile formed within the structure.

### BACKGROUND

1. Field

Embodiments of the present invention generally relates to methods for forming structures on a substrate, and more specifically, for using multiple etching and polymer deposition processes to form structures on a substrate in dual damascene applications.

2. Description of the Related Art

Reliably producing sub-half micron and smaller features is one of the key technology challenges for next generation very large scale integration (VLSI) and ultra large-scale integration (ULSI) of semiconductor devices. However, as the limits of circuit technology are pushed, the shrinking dimensions of VLSI and ULSI interconnect technology have placed additional demands on processing capabilities. Reliable formation of structures accurately formed on the substrate is important to VLSI and ULSI success and to the continued effort to increase circuit density and quality of individual substrates and die.

A patterned mask is commonly used in forming structures, such as contact structure, gate structure, shallow trench isolation (STI), back end dual damascene structure by etching and/or lithography process. The patterned mask is conventionally fabricated using a lithographic process to optically transfer a pattern having desired critical dimensions to a layer of photoresist. The photoresist layer is then developed to remove the undesired portions of the photoresist, thereby creating openings in the remaining photoresist through which underlying material is etched.

In order to enable fabrication of next generation, submicron structures including trenches, vias, or patterned features, having critical dimensions of about 55 nm or less, limitations in the optical resolution of the conventional lithographic processes must be overcome to reliably transfer critical dimensions during mask fabrication. As the geometry limits of the structures for forming semiconductor devices are pushed against technology limits, the lateral dimensions of features of integrated circuits formed on the substrate has shrunk to the point where tighter tolerances and precise process control are critical to fabrication success. However, with shrinking geometries, precise critical dimension and etch profile control has become increasingly difficult. Especially for via fabrication, many processes are inadequate to produce smaller geometry and are limited to about 50 nm to 60 nm in critical dimensions (CD) which are larger than desired and therefore must rely on etch processes to shrink CD during a bottom anti-reflective coating (BARC) and/or an anti-reflective coating (ARC) open process. Another problem found during submicron 55 nm plasma etching processes is control of the sidewall roughness of the etched structure, which may result in formation of anisotropic striation. As the dimensions of the features continue to diminish, the occurrence of sidewall striation and/or post-etch sidewall roughness occurrence in small critical dimension structures pose a significant challenge to structure profile integrity, especially when significant critical dimensions (CD) shrinkage is required during a bottom anti-reflective coating (BARC) and/or an anti-reflective coating (ARC), which may ultimately deteriorate overall device performance.

Furthermore, the conventional lithography technique, e.g., utilizing 193 nm ArF as light source, tends to have resolution limitation on photoresist layers having a thickness greater than 2000 Å. Similarity of each materials, such as a bottom anti-reflective coating (BARC) and/or an anti-reflective coating (ARC) and a photoresist layer, results in similar etch properties therebetween, thereby causing poor selectivity. Poor etching selectivity may result in poor structure integrity, such as non-uniformity or tapered profile formed on the top and/or sidewall of the formed structure on the substrate, thereby eventually leading to device failure. Therefore, high selectivity of an etching process is increasingly important to preserve profiles and thickness of a photoresist layer while etching an underlying target material, such as a bottom anti-reflective coating (BARC) and/or an anti-reflective coating (ARC), a metal layer, a dielectric layer or the like, disposed underneath the photoresist layer.

Therefore, there is a need in the art for improved methods for fabricating small dimension structure, such as trenches and/or vias, on a substrate.

### SUMMARY

Embodiments of the invention include forming small dimensional structures on a substrate using a method that includes multiple processes of polymer deposition and etching. The structures formed on the substrate include vias, trenches, holes, patterned features, and the like. The embodiments described herein may be advantageously utilized to fabricate a submicron structures on a substrate having critical dimensions less than 55 nm and are particularly suitable for dual damascene applications.

In one embodiment, a method of forming a submicron structures on a substrate in a dual damascene application includes providing a substrate having a patterned photoresist layer disposed on a film stack in an etch chamber, wherein the film stack includes a BARC layer disposed on a hardmask layer, supplying a first gas mixture to deposit a polymer on the pattered photoresist layer to reduce a dimension of an opening of the patterned photoresist layer, supplying a second gas mixture to etch the BARC layer through the reduced dimension of the opening of the patterned photoresist layer, and supplying a third gas mixture to etch the hardmask layer through an opening formed in the etched BARC layer.

In another embodiment, a method of forming a submicron structure on a substrate in a dual damascene application includes providing a substrate having a patterned photoresist layer disposed on a film stack in an etch chamber, wherein the film stack includes a BARC layer, a hardmask layer and a dielectric layer sequentially disposed on the substrate, supplying a first gas mixture to deposit a polymer on the pattered photoresist layer to reduce a dimension of an opening of the patterned photoresist layer, supplying a second gas mixture to etch the BARC layer through the reduced dimension of the opening of patterned photoresist layer, and supplying a third gas mixture to etch the hardmask layer through an opening formed in the etched BARC layer until the underlying dielectric layer is exposed.

In yet another embodiment, a method of forming a submicron structure on a substrate in a dual damascene application includes providing a substrate having a patterned photoresist layer disposed on a film stack into an etch chamber, wherein the film stack includes a BARC layer, a hardmask layer and a dielectric layer sequentially disposed on the substrate, wherein the hardmask layer includes a silicon nitride layer disposed on a silicon oxide layer, supplying a first gas mixture to deposit a polymer on the pattered photoresist layer to reduce a dimension of an opening of the patterned photoresist layer, supplying a second gas mixture to etch the BARC layer through the reduced dimension of the opening of patterned photoresist layer, and supplying a third gas mixture to etch the hardmask layer through an opening formed in the etched BARC layer until the underlying dielectric layer is exposed, wherein the third gas mixture etches the hardmask layer while forming a polymer layer on the hardmask layer.

In still another embodiment, an etch chamber coupled to a controller, the controller interfaced with computer readable media, that when executed by the controller, cause a process to be performed in the etch chamber, the process includes depositing a polymer on a patterned photoresist layer such that openings through the photoresist layer are reduced in dimension, etching an opening in a BARC layer through the reduced dimension opening, and etching a hardmask layer to expose a dielectric layer through the opening in the BARC layer.

In yet another embodiment, an etch chamber coupled to a controller, the controller interfaced with computer readable media, that when executed by the controller, cause a process to be performed in the etch chamber, the process comprising supplying a gas mixture including a C₄F₆ gas and a CF₄ gas, wherein C₄F₆ gas deposits a polymer on a patterned photoresist layer such that openings through the photoresist layer are reduced in dimension, while CF₄ gas etches an opening in a BARC layer and a hardmask layer through the reduced dimension opening until an underlying dielectric layer is exposed.

### BRIEF DESCRIPTION OF THE DRAWINGS

The teachings of the present invention can be readily understood by considering the following detailed description in conjunction with the accompanying drawings, in which:

FIG. 1 is a schematic diagram of a plasma processing apparatus used in performing the etching processed according to one embodiment of the invention;

FIG. 2 is a process flow diagram illustrating a method incorporating one embodiment of the invention; and

FIGS. 3A-3G are a sequence of cross-sectional views of a film stack processed to form a ultra thin structure on a substrate.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

Embodiments of the invention generally relate to methods for forming structures on a substrate substantially without sidewall striation and critical dimension loss. The structures formed in the substrate include vias, trenches, holes, patterned features, and the like. In one embodiment, the structures having a critical dimension down to 55 nm or less are formed using multiple processes of polymer deposition and etching process. The method is particularly suitable for etching a bottom anti-refectory coating (BARC) layer (or called anti-refectory coating (ARC) layer) and/or a hardmask layer which is later utilized as a mask layer to etch a dielectric layer as part of a dual damascene fabrication process. The method described herein includes a polymer deposition process and followed by multiple etching process to gradually etch the layers and shrink critical dimension of the structures formed in the layer while maintaining control of structure profile and geometry. By utilizing multiple cycles of polymer deposition and etching, the critical dimension of the structures formed in the layer may be efficiently shank, thereby providing desired sub-micron structure of a desired dimension on the substrate.

The etch and deposition process described herein may be performed in any suitably adapted plasma etch chamber, for example, an ENABLER® etch chamber, available from Applied Materials, Inc., of Santa Clara, Calif. It is contemplated that suitably adapted plasma etch chambers, including those available from other manufacturers, may also be utilized.

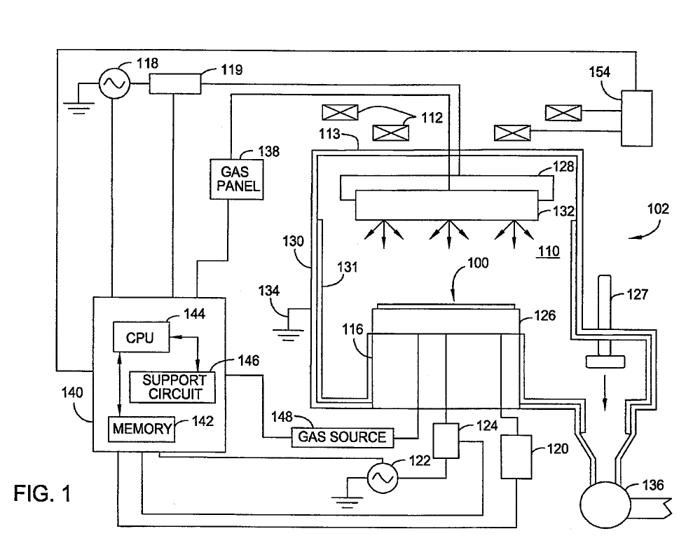

FIG. 1 depicts a schematic, cross-sectional diagram of one embodiment of a plasma source etch reactor 102 suitable for performing the dielectric layer etch according to embodiments of the present invention. In one embodiment, the reactor 102 includes a process chamber 110. The process chamber 110 is a high vacuum vessel that is coupled through a throttle valve 127 to a vacuum pump 136. The process chamber 110 includes a conductive chamber wall 130. The temperature of the chamber wall 130 is controlled using liquid-containing conduits (not shown) that are located in and/or around the wall 130. The chamber wall 130 is connected to an electrical ground 134. A liner 131 is disposed in the chamber 110 to cover the interior surfaces of the walls 130.

The process chamber 110 also includes a support pedestal 116 and a showerhead 132. The support pedestal 116 is disposed below the showerhead 132 in a spaced-apart relation. The support pedestal 116 may include an electrostatic chuck 126 for retaining a substrate 200 during processing. Power to the electrostatic chuck 126 is controlled by a DC power supply 120.

The support pedestal 116 is coupled to a radio frequency (RF) bias power source 122 through a matching network 124. The bias power source 122 is generally capable of producing an RF signal having a tunable frequency of from about 50 kHz to about 60 MHz and a bias power of about 0 to 7,000 Watts. Optionally, the bias power source 122 may be a DC or pulsed DC source. In one embodiment, the bias power source 122 has a low frequency, such as about 13.56 MHz or even lower, or a mixture of one or more frequency as needed.

The temperature of the substrate 100 supported on the support pedestal 116 is at least partially controlled by regulating the temperature of the support pedestal 116. In one embodiment, the support pedestal 116 includes a channels formed therein for flowing a coolant. In addition, a backside gas, such as helium (He) gas, provided from a gas source 148, is provided into channels disposed between the back side of the substrate 100 and grooves (not shown) formed in the surface of the electrostatic chuck 126. The backside He gas provides efficient heat transfer between the pedestal 116 and the substrate 100. The electrostatic chuck 126 may also include a resistive heater (not shown) within the chuck body to heat the chuck 126 during processing.

The showerhead 132 is mounted to a lid 113 of the processing chamber 110. A gas panel 138 is fluidly coupled to a plenum (not shown) defined between the showerhead 132 and the lid 113. The showerhead 132 includes a plurality of holes to allow gases provided to the plenum from the gas panel 138 to enter the process chamber 110. The holes in the showerhead 132 may be arranged in different zones such that various gases can be released into the chamber 110 with different volumetric flow rates.

The showerhead 132 and/or an upper electrode 128 positioned proximate thereto is coupled to an RF source power 118 through an impedance transformer 119 (e.g., a quarter wavelength matching stub). The RF source power 118 is generally capable of producing an RF signal having a tunable frequency of about 13 MHz to about 200 MHz and a source power of about 0 to 5,000 Watts.

The reactor 102 may also include one or more coil segments or magnets 112 positioned exterior to the chamber wall 130, near the chamber lid 113. Power to the coil segment(s) 112 is controlled by a DC power source or a low-frequency AC power source 154.

During substrate processing, gas pressure within the interior of the chamber 110 is controlled using the gas panel 138 and the throttle valve 127. The gas pressure within the interior of the chamber 110 is controllable between about 0.1 to 999 mTorr. The substrate temperature may be controlled between about 10 to about 500 degrees Celsius.

A controller 140, including a central processing unit (CPU) 144, a memory 142 and support circuits 146, is coupled to the various components of the reactor 102 to facilitate control of the processes of the present invention. The memory 142 can be any computer-readable medium, such as random access memory (RAM), read only memory (ROM), floppy disk, hard disk, or any other form of digital storage, local or remote to the reactor 102 or CPU 144. The support circuits 146 are coupled to the CPU 144 for supporting the CPU 144 in a conventional manner. These circuits include cache, power supplies, clock circuits, input/output circuitry and subsystems, and the like. A software routine or a series of program instructions stored in the memory 142, when executed by the CPU 144, causes the reactor 102 to perform an etch process as described below.

FIG. 1 shows only one exemplary configuration of various types of plasma reactors that can be used to practice the invention. For example, different types of source power and bias power can be coupled into the plasma chamber using different coupling mechanisms. Using both the source power and the bias power allows independent control of a plasma density and a bias voltage of the substrate with respect to the plasma. In some applications, the source power may not be needed and the plasma is maintained solely by the bias power. The plasma density can be enhanced by a magnetic field applied to the vacuum chamber using electromagnets driven with a low frequency (e.g., 0.1-0.5 Hertz) AC current source or a DC source. In other applications, the plasma may be generated in a different chamber from the one in which the substrate is located, e.g., remote plasma source, and the plasma subsequently guided into the chamber using techniques known in the art.

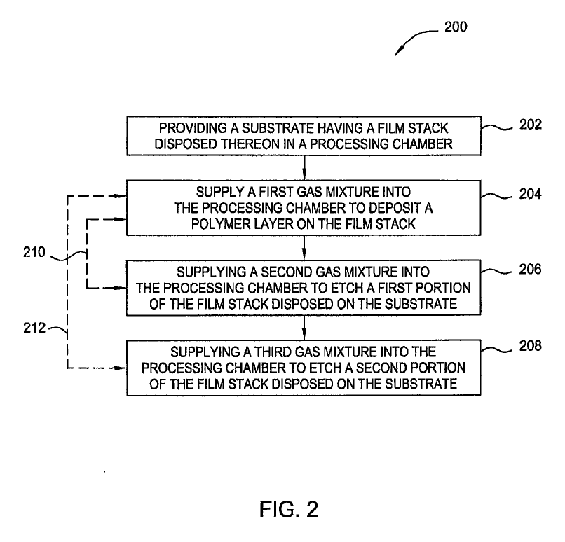

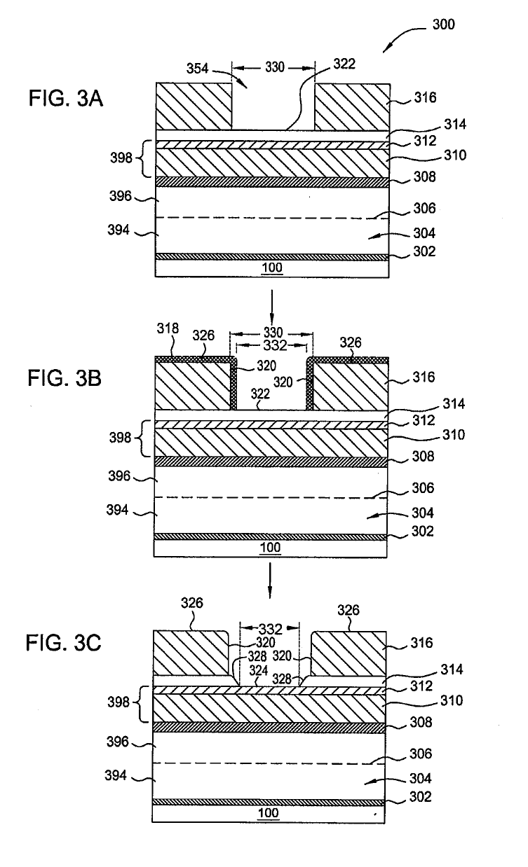

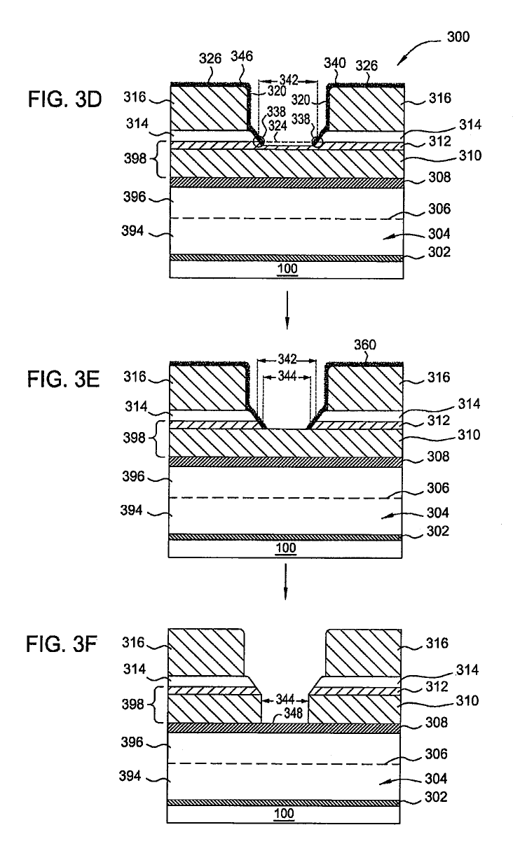

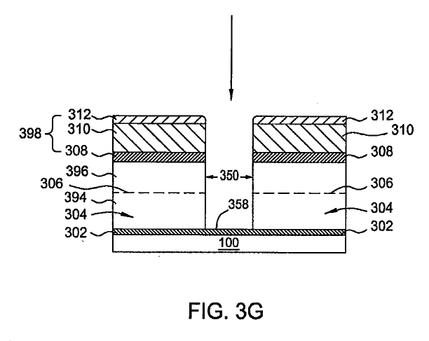

FIG. 2 depicts a flow diagram of one embodiment of an etch process 200 that may be practiced in the reactor 102, as described in FIG. 1, or other suitable processing chamber. FIGS. 3A-3G are schematic cross-sectional views of a portion of a composite substrate corresponding to various stages of the process 200. The process 200 described with connection to FIG. 3A-3G may be beneficially utilized to fabricate a dual damascene structure of a semiconductor device or the like. The process 200 is an exemplary embodiment that generally illustrates the sequence of forming structures in a bottom anti-refectory coating (BARC)/anti-refectory coating (ARC) layer and/or a hardmask layer as etch mask layers for etching a dielectric layer disposed on a substrate in dual damascene applications. However, it is contemplated that the process 200 may be adapted to other applications, such as any etching process including conductor or dielectric etching, in which the structures formed on the substrate need critical dimension shrinkage during the etching process.

The process 200 begins at block 202 by providing the substrate 100 having a film stack 300 disposed thereon, as shown in FIG. 3A. In the embodiment depicted in FIG. 3A, the film stack 300 has a patterned photoresist layer 316. In an exemplary embodiment, the film stack 300 is suitable for fabricating a dual damascene structure, but may alternatively be configured to fabricate other structures. The substrate 100 may be any one of semiconductor substrates, silicon wafers, glass substrates and the like. In one embodiment, the substrate 100 may have field effect transistors, such as gate structure, silicide or oxide, source and drain structures formed therein.

In one embodiment, the film stack 300 includes the patterned photoresist layer 316 disposed on a bottom anti-refectory coating (BARC)/anti-refectory coating (ARC) layer 314 and a hardmask layer 398. The hardmask layer 398 may be in form of a single layer, dual layer, or multiple layers. An optional middle etch stop layer 308 may be disposed between the hardmask layer 398 and a dielectric layer 304. An optional bottom etch stop layer 302 may be disposed on the substrate 100 below the dielectric layer 304.

The patterned photoresist layer 316 (e.g. a photomask layer) is disposed on the top of the BARC/ARC layer 314. At least a portion 322 of the BARC/ARC layer 314 is exposed for etching through openings 396 defined in the photoresist layer 316. The exposed portions 322 of the BARC/ARC layer 314 may be readily etched, as will be further described below.

In one embodiment, the BARC/ARC layer 314 may be spin-applied on the substrate 100. The BARC/ARC layer 314 may include, for example, organic materials such as SOG, polyamides and polysulfones typically having hydrogen and carbon containing elements, or inorganic materials such as silicon nitride, silicon oxynitride, silicon carbide, and the like. In the embodiment depicted in FIG. 3A, the BARC/ARC layer 314 is an organic material spun-on the substrate 100. In another embodiment, the BARC/ARC layer 314 may be coated, deposited, or otherwise disposed on the substrate 100 by another suitable manner. In one embodiment, the BARC/ARC layer 314 has a thickness between about 300 Å and about 2000 Å, such as between about 600 Å and about 1000 Å.

The hardmask layer 398 may be in form of a single layer selected from a group consisting of silicon oxide, silicon nitride, silicon carbide, silicon nitride carbide (SiCN), silicon oxynitride (SiON), amorphous silicon (α-Si) or SOG, among other silicon films. Alternatively, the hardmask layer 398 may be in form of a composite film including at least two layers 312, 310 selected from the materials described above. In the embodiment depicted in FIG. 3A, the hardmask layer 398 has two layers 312, 310. The first upper layer 312 is a silicon nitride (SiN) layer and the second lower layer 310 is a silicon oxide (SiO₂) layer. In one embodiment, the first upper layer 312 has a thickness between about 250 Å and about 1500 Å, such as between about 500 Å and about 1000 Å, such as about 750 Å. The second lower layer 310 has a thickness between about 500 Å and about 2500 Å, such as between about 1000 Å and about 2000 Å.

The optional middle etching stop layer 308 may be a dielectric layer having a film property different from that of the hardmask layer 398 to provide a good selectivity therebetween during etching process. In one embodiment, the optional middle etching stop layer 308 may be silicon nitride, silicon carbide, silicon nitride carbide (SiCN) and silicon oxynitride (SiON), among other silicon films. One example of the optional middle etching stop layer 308 is a silicon carbon film (SiC). In one embodiment, the optional middle etching stop layer 308 has a thickness between about 0 Å and about 1500 Å, such as between about 200 Å and about 700 Å.

In one embodiment, the dielectric layer 304 is a dielectric material having a dielectric constant less than 4.0. Examples of suitable materials include carbon-containing silicon oxides (SiOC), such as BLACK DIAMOND® dielectric material available from Applied Materials, Inc., or other polymers, such as polyamides. The dielectric layer 304 may be in form of a single layer or multiple layers. In the embodiment depicted in FIG. 3A, the dielectric layer 304 may be in form of two layers 396, 394, as separated by an imaginary line 306. The two layers 396, 394 included in the dielectric layer 304 may have similar film properties utilized to form vias and trenches respectively in the dielectric layer 304. In an exemplary embodiment, the upper portion 396 above the imaginary line 306 may be utilized to form trenches and the lower portion 394 below the dotted line 306 may be utilized to form vias in the dielectric layer 304, in combination forming a desired dual damascene structure on the substrate 100. Alternatively, the dual damascene structure may be formed in a unitary single dielectric layer 304. In one embodiment, the thickness of the dielectric layer 304 may be in total of between about 1500 Å and about 4000 Å.

The optional bottom etching stop layer 302 may be a dielectric layer similar to the middle etching stop layer 308, as described above, having a film property different from that of the upper dielectric layer 304 so as to provide a good selectivity therebetween during etching process. In one embodiment, the bottom etching stop layer 302 may be selected from a group consisting of silicon nitride, silicon carbide, silicon nitride carbide (SiCN) and silicon oxynitride (SiON), among other silicon films. One example of the optional middle etching stop layer 308 described herein is a silicon carbon film (SiCN). In one embodiment, the optional middle etching stop layer 308 has a thickness between about 200 Å and about 1000 Å.

In the embodiment depicted in FIG. 3A, the BARC/ARC layer 314 is a SOG layer and referred as a BARC layer herein. The hardmask layer 398 may be a composite film having a silicon nitride layer 312 disposed on a silicon oxide (SiO₂) layer 310. The optional middle etching stop layer 308 may be a silicon carbon (SiC) film. The dielectric layer 304 may be a carbon-containing silicon oxide layer (SiOC). The bottom etch stop layer 302 may be a silicon carbon nitride layer (SiCN). The photoresist layer 316 has been patterned by a conventional lithographic process and has openings 354 having an initial critical dimension 330 which exposes a portion 322 of the underlying BARC/ARC 314 for etching.

At block 204, a first gas mixture is supplied into the processing chamber to deposit a polymer layer 318 on a sidewall 320 of the openings 396 and an upper surface 326 of the patterned photoresist layer 316, as shown in FIG. 3B. The deposition of polymer layer 318 is controlled in a manner that mainly deposits on the sidewalls 320 rather than upper surface 326 of the patterned photoresist layer 316. As polymers 318 are deposited on the sidewalls 320 of openings 396 of the patterned photoresist layer 316, the initial critical dimension 330 of openings 328 is reduced/shrank by the thickness of the deposited polymer 318, and thus narrowing and the effective dimension of the opening 330 to a pre-defined and reduced dimension 332. By depositing polymer 318 on the sidewalls 320 of openings 396, the critical dimension of the openings 396 is shrank, thereby providing structures with desired shrank submicron critical dimension structure on the substrate after etching. In one embodiment, the first gas mixture includes at least a polymer gas and an etching gas. The polymer gas deposits polymers 318 on the patterned photoresist layer 316 while the etching gas assists in controlling the accumulation and the deposition of the polymers 318 formed on the substrate. The polymer gas may include polymer rich chemistry. The polymer rich chemistries typically have a formula CₓH_{y}F_{z}, where x, y and z are integers greater than 0, such as CH₃F, CH₂F₂, CHF₃, CH₃F, C₄F₈, C₄F₆, and the like. Alternatively, the polymer rich chemistries may be a carbon based gas. Suitable examples of polymer rich chemistries include CH₄, C₂H₄, C₃H₈, C₃H₆, COS, combinations thereof, and the like. The etching gas includes polymer lean etching gas, such as CF₄. Other suitable examples of lean gases include N₂, O₂ combinations thereof, and the like. In some embodiments, the polymer gas may be selected to have functions performed both as polymer gas and etching gas. For example, in the embodiments wherein the polymer gas is selected to have both carbon and fluorine elements, the polymer gas may deposit polymer layer on the substrate while slightly etching the substrate. The polymer deposition and etching rate maybe controlled by the ratio between the carbon and fluorine element included in the polymer gas or the process parameters used during the deposition process.

In one embodiment, the ratio of the etching gas and the polymer gas supplied in to the first gas mixture may be controlled from about 5:1 to about 1:5, such as about 3:1 to about 1:3. The ratio of the etching gas and the polymer gas may be efficiently controlled to provide a desired amount of polymer on the substrate, thereby preventing excess polymer from accumulating on the upper surface 322 of the substrate. The balanced and controlled amount of polymer gas and the etching gas reduces the occurrence deposition of non-uniformly formed on the patterned photoresist layer 316, thereby preventing striation or non-uniform profile formed on the patterned photoresist layer 316 during the etching process.

In the embodiment wherein CF₄ gas is selected as etching gas and CH₂F₂ is selected as polymer gas, the ratio between the CF₄ and the CH₂F₂ is about 3:1. In the embodiment wherein CF₄ gas is selected as etching gas and CHF₃ is selected as polymer gas, the ratio between the CF₄ gas and CHF₃ gas is about 2:1. It is noted that ratio between the etching gas and the polymer gas may be varied in accordance with the different gas species selected for the reaction. Other process gases, such as Ar and He, may also be included with the polymer gas into the etch chamber to adjust plasma profile and maintain the process pressure at a desired range.

Several process parameters may also be regulated during processing. In one embodiment, the chamber pressure in the presence of the first gas mixture is regulated between about 20 mTorr to about 300 mTorr, for example, at about 100 mTorr. RF bias power may be applied to maintain a plasma formed from the polymer gas mixture. For example, a bias power having a frequency of about 13.56 MHz is controlled between about 100 Watts to about 1000 Watts, such as between about 300 Watts and about 500 Watts, for example, about 400 Watts to maintain a plasma inside the etch chamber. Alternatively, one or more bias power at different frequencies may be used to maintain a plasma inside the etch chamber. The polymer gas may be flowed into the chamber at a rate between about 10 sccm to about 500 sccm, for example, between about 10 and about 50 sccm. The etching gas mixture may be flowed into the chamber at a rate between about 25 sccm to about 1000 sccm, for example, between about 100 and about 500 sccm, such as about 250 sccm. The inert gas may be supplied at a flow rate about 0 sccm and about 800 sccm, such as about 100 sccm. A substrate temperature may be maintained between about 10 degrees Celsius to about 500 degrees Celsius, for example, about 15 degrees Celsius to about 80 degrees Celsius, such as about 25 degrees Celsius.

At block 206, after a sufficient amount of polymer 318 has been deposited to reduce the initial critical dimension 330 to the reduced dimension 332, a second gas mixture is supplied into the processing chamber to perform a BARC/ARC open etching process. The BARC/ARC open process is performed to etch the underlying BARC/ARC layer 314 through the reduced dimension 322 defined between the polymer 318 lining the sidewalls 320 of the opening 354 until an underlying surface 324 of the hardmask layer 398 is exposed, as shown in FIG. 3C. Alternatively, the BARC/ARC open process may also be performed to etch the BARC/ARC layer 314 until the underlying hardmask layer 398 is at least partially etched, as shown in FIG. 3D, based on different process requirements. During etching, the polymer 318 may be at least partially consumed by the attack of the reactive etchants present in the gas mixture. As the polymer 318 may be gradually consumed from the sidewall 320 of the patterned photoresist layer 316, the effective area of the reduced dimension is gradually enlarged. As the reduced dimension 322 of the opening 354 is enlarged, the exposed area of the underlying BARC/ARC layer 314 is correspondingly increased, which may result in tapered and/or sloped profile 328 formed on the corners/upper portion of the etched BARC/ARC layer 314.

In one embodiment, the second gas mixture supplied for BARC/ARC open etch process includes lean chemistries, such as CF₄, and the like. In some embodiments, a small amount of polymer gas may also be supplied in the second gas mixture to maintain the sufficient amount of polymers remained on the substrate to keep shrinking the dimension 332 of the opening 396 and prevent the dimension 332 from being re-opened or broadened. Suitable examples of the polymer gas include CH₃F, CH₂F₂, CHF₃, CH₃F, C₄F₈, C₄F₆, similar to the polymer gas used in the first gas mixture, as described at block 204. As the second gas mixture is arranged for BARC/ARC open process, the amount of the lean chemistries included in the second gas mixture is significantly greater than the amount of polymer gas included in the second gas mixture. In one embodiment, the ratio of the etching gas and the polymer gas supplied in to the second gas mixture may be controlled from about 20:1 to about 1:1, such as about 10:1 to about 2:1. In the embodiment wherein CF₄ gas is selected as etching gas and CH₂F₂ is selected as polymer gas, the ratio between the CF₄ and the CH₂F₂ is about 6:1. In the embodiment wherein CF₄ gas is selected as etching gas and CHF₃ is selected as polymer gas, the ratio between the CF₄gas and CHF₃ gas is about 8:1. It is noted that ratio between the etching gas and the polymer gas may be varied in accordance with the different gas species selected for the reaction. A carrier gas, such as Ar, He, or N₂, may also be optionally supplied in the second gas mixture into the etch chamber.

Several process parameters may also be regulated during etching. In one embodiment, the chamber pressure in the presence of the second gas mixture is regulated between about 3 mTorr to about 200 mTorr, for example, at about 80 mTorr. RF bias power may be applied to maintain a plasma formed from the etching gas mixture. For example, a RF bias power of about 100 Watts to about 2000 Watts, such as between about 800 Watts and about 1000 Watts, may be applied to maintain a plasma inside the etch chamber. In order to efficiently maintain the vertical etching behavior, e.g., anisotropic etching, during the BARC/ARC open process to mainly etch the BARC/ARC layer 314 rather than consuming the upper polymer 318 and photoresist layer 316, a relatively higher RF bias power, e.g., higher than the bias power utilized in the first gas mixture described at block 204, is used to perform the BARC/ARC open process. For example, a higher bias power, such as between about 100 Watts and about 800 Watts higher than the bias power applied in the first gas mixture, may be used in the second gas mixture. Furthermore, a dual frequency of RF power may be used along with the selected etching gas chemistries, as described above, to eliminate microloading effect during the etching process. In one embodiment, the frequencies used for the RF bias powers may be about 13 MHz and 2 MHz respectively. Additionally, a relatively lower process pressure may be used to assist maintain the higher RF bias power in the second gas mixture. For example, a lower process pressure, such as between about 30 mTorr or about 100 mTorr lower than the process pressure maintained in the first gas mixture, may be used in the second gas mixture. The polymer gas may be flowed into the chamber at a rate between about 0 sccm to about 200 sccm. The etching gas mixture may be flowed into the chamber at a rate between about 50 sccm to about 800 sccm, such as about 600 sccm. The inert gas may be supplied at a flow rate about 0 sccm and about 800 sccm, such as between about 5 sccm and about 400 sccm. A substrate temperature may be maintained between about 10 degrees Celsius to about 500 degrees Celsius, such as about 50 degrees Celsius.

By utilizing the desired ratio of the etching gas and polymer gas, a relatively higher bias power and a relatively lower process pressure control maintained in the second gas mixture, a BARC/ARC open process with good profile control, e.g., striation free and maintained shrank critical dimension of the formed structure, may be obtained.

In an alternative embodiment, a multiple cycles of polymer deposition of block 204 and BARC/ARC open etch process of block 206 may be performed repeatedly, as indicted by loop 210, until the underlying upper surface 324 of the hardmask layer 398 is exposed and/or partially etched. The multiple cycles of the polymer deposition and the BARC/ARC open etch process allows the BARC/ARC layer 314 being incrementally etched, thereby substantially eliminating the potential for tapered and/or sloped profiles formed in the etched BARC/ARC layer 314. The multiple cycles of the polymer deposition and the BARC/ARC open process also assists maintaining a constant thickness of the polymer layer, which may be consumed during etching, thereby maintaining the open area defined by the reduced dimension 332 while the BARC/ARC layer is etched through. It is noted that the numbers of cycles performed to etch the BARC/ARC layer 314 may be performed as many times as needed. Additionally, the frequency of each cycle may be selected to control the taper of the profile 328. For example, the BARC/ARC layer 314 having higher thickness may need higher number of cycles to remove the BARC/ARC layer 314. In one embodiment wherein the BARC/ARC layer has a thickness greater than about 1000 Å, at least two or more cycles of the polymer deposition of block 204 and BARC/ARC open etch process of block 206 may be performed.

At block 208, a third gas mixture is supplied into the processing chamber to etch the underlying hardmask layer 398 through the opening 396 defined through the etched BARC/ARC layer 314 having reduced critical dimension 332, as shown in FIG. 3D. The process gases supplied in the third gas mixture are selected to etch the hardmask layer 398 while forming a protection layer on the hardmask layer 398. The protection layer formed on the hardmask layer 398 during etching protects corners 338 of the hardmask layer 398, thereby preventing irregular profile, defects and striation formed during the subsequent etching processes. The third gas mixture also provides a high selectivity of the hardmask layer 398 to the patterned photoresist layer 316 and BARC/ARC layer 314 so that the hardmask layer 398 is predominantly etched without attacking the mask layers, e.g., upper photoresist layer 316 and BARC/ARC layer 314, thereby preserving a good control of the profile and dimension of the patterned mask layers during hardmask etching.

In one embodiment wherein the hardmask layer 398 includes a first upper layer 312 and the second lower layer 310, the third gas mixture supplied may be configured to etch the first upper layer 312, or etch the first upper layer 312 and partially etch the second lower layer 310, or etch both the first upper layer 312 and the second lower layer 310, or any different arrangements or configuration as needed. In one embodiment, the third gas mixture includes an etching gas and a polymer gas that may provide reactive species as well as passivation species to simultaneously etch the hardmask layer 398 while forming a polymer layer thereon on the substrate. The third gas mixture deposits a thin layer 340 of polymer layer that protects the upper corners 320 of the hardmask layer 314 while etching the exposed surface 324 of the hardmask layer 398. In one embodiment, the third gas mixture is selected substantially the same as the first gas mixture used at block 204. As the third gas mixture includes the polymer gas and the etching gas, the ratio and/or composition of the polymer gas and the etching gas is selected to manage the polymer deposition and consumption rate to maintain a desired shrank dimension during etching. As the polymer may be maintained at a desired amount while etching the hardmask layer 398, the degree of the critical dimension shrinkage may be efficiently controlled by varying the ratio between the polymer gas and the etching gas, as performed at block 204. The polymer formed on the substrate may keep shrinking the dimension of the opening 342, thereby forming a desired structure with reduced desired dimension. Additionally, the polymer formed on the substrate may also prevent striation formed on the substrate and provide a uniform and desired profile and dimension on the substrate.

In one embodiment, the polymer gas includes at least one of CH₃F, CH₂F₂, CHF₃, CH₃F, C₄F₈, C₄F₆, and the like and the etching gas includes CF₄ and the like. In one embodiment, the ratio of the etching gas and the polymer gas supplied in to the first gas mixture may be controlled from about 5:1 to about 1:5, such as about 3:1 to about 1:3. The ratio controlled between the etching gas and the polymer gas may be efficiently controlled to provide a desired amount of polymer being deposited on the substrate while continuing to etching the hardmask layer 398. Additionally, the critical dimension shrinkage of the hardmask layer 398 may be dynamically controlled and varied by adjusting the amount of the polymer gas supplied in the third gas mixture during the etching process. Accordingly, the degree of the critical dimension shrinkage of the structures formed on the substrate may be adjusted based on selecting different materials and process gases for different process requirements.

In the exemplary embodiment depicted in FIG. 3D wherein the hardmask layer 398 includes the first upper layer 312 and the second lower layer 310, the etching gas etches the exposed surface 324 of the first upper layer 312 while the polymer gas forms the thin polymer layer 340 that protects the profile of the etched first upper layer 312 without creating undesired striation. Furthermore, the thickness of the thin polymer layer 340 may further increase to reduce and shrink the width of the opening 396 defined through the patterned photoresist layer 316 and BARC/ARC layer 314, similar to the polymer layer formed in block 204, thereby assisting in shrinking the dimension 342 of the pafterned photoresist layer 316 and BARC/ARC layer 314 during the etching process. The degree of the dimension shrinkage may be determined by the amount of polymer gas supplied in the third gas mixture that deposits the thin polymer layer 340 on the substrate 100. As the thin polymer layer 340 may be at least partially consumed during etching, a taped and/or sloped profile may be formed in the first upper layer 312 with narrowed dimension 344, as shown in FIG. 3E.

Furthermore, in order to consistently maintain the narrowed/shrank dimension defined by the thin polymer layer 340 lining the opening 396 while maintaining the high selectivity to the upper photoresist layer 316, different types of the polymer gas having both etching and polymer deposition functions may be supplied in the third gas mixture to adjust and control the etching process. In the embodiments wherein the etching rate is desired to be higher than the polymer depositing rate, the etching gases may be selected to have a relatively high fluorine to carbon ratio. The relatively high fluorine to carbon ratio etching gas, such as C₄F₈, may have higher reactivity than those etching gas having relatively low fluorine ratio, such as C₄F₆. The etching gas having higher fluorine ratio to carbon tends to attack the hardmask layer 398 as well as the upper photoresist 316 and BARC/ARC layer 314, resulting in poor selectivity between each layers, thereby leading to poor profile control and striations in the formed structure in the hardmask layer 398. In contrast, etching gases having high carbon to fluorine ratio tends to form polymers on the surfaces of the substrate. The excess polymer generated from the higher carbon ratio etching gas may result in by-products and/or residuals being left on the substrate surface. By adjusting the ratio between different types of the etching gases and polymer gas used in the third gas mixture each having high and low ratios of fluorine to carbon elements into the gas mixture, the selectivity between the hardmask layer 398 and the upper mask layers and lower etching stop layer 308 may be efficiently controlled. Additionally, the microloading effect found in the conventional techniques may also be eliminated by providing a greater quantity of the polymerizing gas in the low density area while providing a lower quantity of etching gas in the high density area, or vise versa. In one embodiment, the etching gas may be simultaneously etching and forming thin polymer layer on the substrate using gases selected from a group consisting of CF₄, C₄F₆, CHF₃, CH₄, CH₃F, CH₂F₂, C₄F₈ and the like.

In the embodiment wherein CF₄ gas is selected as etching gas and CH₂F₂ is selected as polymer gas, the ratio between the CF₄ and the CH₂F₂ is about 3:1. In the embodiment wherein CF₄ gas is selected as etching gas and CHF₃ is selected as polymer gas, the ratio between the CF₄ gas and CHF₃ gas is about 2:1. It is noted that ratio between the etching gas and the polymer gas may be varied in accordance with the different gas species selected for the reaction. Other process gases, such as Ar, or He, may also be included with the polymer gas into the etch chamber.

In one particular embodiment, the gases for the third gas mixture may be selected to both have etching and polymer deposition functions. For example, the gas selected for the third gas mixture to etch the hardmask layer 398 is C₄F₆. C₄F₆ provides fluorine reactive species to etch the hardmask layer 398 while provides carbon species to assist depositing polymer on the substrate. In this embodiment, the hardmask layer 398 may be in form of a single layer, such as a silicon oxide layer. Furthermore, an oxygen containing gas may be supplied in the third gas mixture. Suitable examples of an oxygen containing gas include O₂, NO₂, N₂O, CO₂, and the like. An inert gas or carrier gas, such as Ar, He, and CO, may also be supplied in the gas mixture.

Additionally, a multiple cycles of the first gas mixture and the second gas mixture as described in block 204 and 206 respectively may be alternatively supplied into the process chamber, as indicated by the loop 212, to assist etching the first upper layer 312 included in the hardmask layer 398. The multiple cycles of polymer deposition and BARC/ARC open etching allows polymers to be gradually re-deposited on the patterned photoresist layer 316, thereby allowing the underlying hardmask layer 398 to be gradually etched in a controlled manner at critical dimensions less that what could reliably be achieved using conventional lithographic mask-then-etch techniques. The gradual and sequential re-deposition and etching process prevents the BARC/ARC 314 and the hardmask layer 398 from being over aggressively etched, thereby avoiding unwanted striation and/or causing poor critical dimension transfer to the structure formed in the film stack 300.

Several process parameters may be regulated during dielectric etching processing. In one embodiment, the chamber pressure in the presence of the third gas mixture may be regulated between about 2 mTorr to about 200 mTorr, for example, at about 100 mTorr. RF source power may be applied to maintain a plasma formed from the third gas mixture. For example, a bias source power of about 100 Watts to about 2000 Watts may be applied to maintain a plasma inside the etch chamber. Additionally, a dual frequency of RF power may be used along with the selected etching gas chemistries, as described above, to eliminate microloading effect during the etching process. In one embodiment, the frequencies used for the RF bias power may be about 13 MHz and 2 MHz respectively. The third gas may be flowed into the chamber at a rate between about 0 sccm to about 200 sccm. The inert gas may be supplied at a flow rate about 0 sccm and about 1500 sccm. A substrate temperature may be maintained between about 10 degrees Celsius to about 500 degrees Celsius, such as about 20 degrees Celsius.

After completion of the first upper layer etching process, the patterned/etched first upper layer 312 may be utilized as an etch mask layer for etching the underlying, second lower layer 310 of the hardmask layer 310. The second lower layer etching 310 may be etched until an upper surface 348 of the underlying optional middle etching stop layer 308 is exposed, as shown in FIG. 3F. In one embodiment, the first upper layer 312 and the second lower layer 310 may be etched in one etching process using the same third gas mixture utilized at block 208.

After the upper BARC/ARC 314 and the hardmask layer 398 has been opened, the underlying optional middle etching stop layer 308 and the dielectric layer 304 are exposed for forming vias of a dual damascene structure with a desired shank via critical dimension 350, as shown in FIG. 3G. In one embodiment, the stop layer 308 and dielectric layer 304 are etched until an upper surface 358 of the optional bottom etching stop layer 302 is exposed. In the embodiment wherein some portion of the photoresist layer 316 and the BARC/ARC layer 314 are remaining on the substrate, an ashing process may be performed to remove the remaining photoresist layer 316 and the BARC/ARC layer 314 from the substrate 100.

As the first, the second, and the third gas mixture supplied at block 204, 206, and 208, utilized to perform the BARC/ARC open process, the critical dimension of the structures formed within the substrate is defined. The process defines structure features have a dimension smaller than 60 nm and beyond. In the embodiment wherein the hardmask layer 298 has a thick thickness or multiple layers, the process parameters, such as RF power or the amount or flow rate of the process gases supplied into the processing chamber may be smoothly transitioned in between each process and each gas mixture to gradually etch the hardmask layer 298 until the underlying substrate, such as the optional middle etch stop layer 308, as shown in FIG. 3G, is exposed.

The process 200, as described in FIG. 2, may be performed to form features and/or structures on the substrate. In one embodiment, the film stack 300 disposed on the substrate 100 may be etched to form a “via-first” dual damascene structure for back end of the line structures on the substrate 100. After the etching process 200 has been completed, vias that may be utilized as a portion of the dual damascene structure are formed within the dielectric layer 304 with desired reduced critical dimension and width as compared to conventional techniques.

It is noted that the process 200 may be performed in a single chamber. By switching different gas mixtures and process parameters at different stages of the etching process, a “via-first” dual damascene structure may be formed on a substrate with good submicron critical dimensions transfer. Although the exemplary embodiment of the etching method described herein is used to form a dual damascene structure, it is noted that the etching method may be utilized to form other structures.

Alternatively, in some embodiment, one etching process may be performed to etch the file stack 300. In the embodiment wherein the hardmask layer 398 is in form of a single layer, such as a silicon oxide layer, the BARC/ARC 314 and at least partially of the hardmask layer 398 may be etched by the one etching process. During etching, a gas mixture including at least a lean etching gas and a polymer gas may be supplied to etch the BARC/ARC layer 314 and the at least partial hardmask layer 398. As the gas mixture is used to etch several different materials, e.g. the BARC/ARC 314 and the at least partial hardmask layer 398, disposed on the substrate 100, the etching gas may be selected from a leaner chemistry that has high etching capability. The polymer gas may be selected from a more polymerized gas that has high polymer formation capability, thereby allowing the gas mixture to etch the film stack 300 while forming a sufficient amount of polymer during etching. The polymer gas in the gas mixture supplies and generates polymer during the one etching process, thereby shrinking the dimension 332 of the opening 396 while etching the film stack 300, as discussed above, and preventing the dimension 332 from being re-opened or broadened.

In one embodiment, the lean chemistry used as etching gas for one etching process is CF₄. The polymer chemistry used as polymer gas for one etching process is C₄F₈. A carrier gas, such as Ar, He, O₂or N₂, may also be optionally supplied in the gas mixture into the etch chamber.

Several process parameters may also be regulated during etching. In one embodiment, the chamber pressure in the presence of the second gas mixture is regulated between about 3 mTorr to about 200 mTorr, for example, at about 80 mTorr. RF bias power may be applied to maintain a plasma formed from the etching gas mixture. For example, a RF bias power of about 100 Watts to about 2000 Wafts, such as between about 800 Watts and about 1000 Watts, for example about 1000 Watts, may be applied to maintain a plasma inside the etch chamber. Furthermore, a dual frequency of RF power may be used along with the selected etching gas chemistries, as described above, to eliminate microloading effect during the etching process. In one embodiment, the frequencies used for the RF bias powers may be about 13 MHz and 2 MHz respectively. The polymer gas may be flowed into the chamber at a rate between about 0 sccm to about 200 sccm, such as about 0 sccm and about 100 sccm, for example about 1 sccm and about 15 sccm. The etching gas mixture may be flowed into the chamber at a rate between about 0 sccm to about 500 sccm, such as about 0 sccm and about 300 sccm, for example about 50 sccm and about 150 sccm. The inert gas may be supplied at a flow rate about 0 sccm and about 800 sccm, such as between about 5 sccm and about 400 sccm. A substrate temperature may be maintained between about 10 degrees Celsius to about 500 degrees Celsius, such as about 50 degrees Celsius.

It is noted that the one etching process may be used in a front end etching process, such as a contact, or a high aspect ratio etching process. The dielectric layer 304 used for the front end process may be a silicon oxide based containing material selected from a group consisting of SiO₂, TEOS, USG, BSG, PSG and BPSG. As the dielectric layer 304 as described here are silicon oxide based layers, the BARC/ARC layer 314 may be directly disposed on the dielectric layer 304, one type of material similar to the materials for hardmask layer 398. As the dielectric layer 304 is selected from a material similar to the hardmask layer 398, the hardmask layer 398 and other intervening layers disposed therebetween may be eliminated. In this particular embodiment, the one etching process is utilized to open the BARC/ARC layer 314 and at least partial of the dielectric layer 304. Alternatively, the one etching process may be used in any different applications as needed.

Thus, embodiments of the present invention provide an improved method for forming a structure on a substrate. The structure is particularly suitable for dual damascene applications having a submicron critical dimensions less than 55 nm and beyond. The present invention advantageously provides a manner for forming structures on a substrate by multiple cycles of polymer deposition process and mask open etching process, thereby preventing striation and critical dimension loss of the etched structures.

While the foregoing is directed to embodiments of the present invention, other and further embodiments of the invention may be devised without departing from the basic scope thereof, and the scope thereof is determined by the claims that follow.

What is claimed is:

1. A method of forming a submicron structure on a substrate suitable for a dual damascene application, comprising:
(a) providing a substrate having a patterned photoresist layer disposed on a film stack in an etch chamber, wherein the film stack includes a BARC layer disposed on a hardmask layer;
(b) supplying a first gas mixture to deposit a polymer on the pattered photoresist layer to reduce a dimension of an opening in the patterned photoresist layer;
(c) supplying a second gas mixture to etch the BARC layer through the reduced dimension of the opening of patterned photoresist layer; and
(d) supplying a third gas mixture to etch the hardmask layer through the opening formed in the etched BARC layer.

2. The method of claim 1, further comprising:
exposing the underlying hardmask layer through the opening formed in the etched BARC layer etched through the reduced dimension opening of the patterned photoresist layer.

3. The method of claim 1, further comprising:
repeating (b) and (c) until the underlying hardmask layer is exposed.

4. The method of claim 1, wherein the film stack further includes a dielectric layer disposed between the hardmask layer and the substrate.

5. The method of claim 4, further comprising:
etching the dielectric layer through the opening in the etched hardmask layer.

6. The method of claim 4, further comprising:
repeating (b)-(d) until the underlying dielectric layer is exposed.

7. The method of claim 1, wherein (d) supplying the third gas mixture further comprises:
forming a polymer layer on the hardmask layer while etching the hardmask layer.

8. The method of claim 1, wherein the hardmask layer includes a silicon nitride layer disposed on a silicon oxide layer.

9. The method of claim 4, wherein the film stack further includes an etch stop layer disposed between the hardmask layer and the dielectric layer.

10. The method of claim 1, wherein the first gas mixture includes an etching gas and a polymer gas, wherein the ratio of the etching gas and the polymer gas supplied in the first gas mixture is controlled between about 5:1 and about 1:5.

11. The method of claim 1, wherein the second gas mixture further comprises at least one of CF₄, C₄F₆, C₂H₂F₂, CHF₃, CH₃F, CO, CO₂, O₂, NH₃, H₂, SO₂, CH₄, C₂H₄, C₃H₈ or C₃H₆.

12. The method of claim 1, wherein the third gas mixture is substantially the same as the first gas mixture.

13. The method of claim 1, wherein the supplying the third gas mixture further comprises:
applying dual frequency RF power into the processing chamber.

14. A method of forming a submicron structure on a substrate suitable for a dual damascene application, comprising:
(a) providing a substrate having a patterned photoresist layer disposed on a film stack in an etch chamber, wherein the film stack includes a BARC layer, a hardmask layer and a dielectric layer sequentially disposed on the substrate;
(b) supplying a first gas mixture to deposit a polymer on the pattered photoresist layer to reduce a dimension of an opening in the patterned photoresist layer;
(c) supplying a second gas mixture to etch the BARC layer through the reduced dimension opening in patterned photoresist layer; and
(d) supplying a third gas mixture to etch the hardmask layer through an opening formed in the etched BARC layer until the underlying dielectric layer is exposed.

15. The method of claim 14, wherein supplying the third gas mixture further comprises:
forming a polymer layer on the hardmask layer while etching the hardmask layer.

16. The method of claim 14, wherein the hardmask layer includes a silicon nitride layer disposed on a silicon oxide layer.

17. The method of claim 14, wherein the film stack further includes an etch stop layer disposed between the dielectric layer and the hardmask layer.

18. A method of forming a submicron structure on a substrate suitable for a dual damascene application, comprising:
(a) providing a substrate having a patterned photoresist layer disposed on a film stack in an etch chamber, wherein the film stack includes a BARC layer, a hardmask layer and a dielectric layer sequentially disposed on the substrate, wherein the hardmask layer includes a silicon nitride layer disposed on a silicon oxide layer;
(b) supplying a first gas mixture to deposit a polymer on the pattered photoresist layer to reduce a dimension of an opening in the patterned photoresist layer;
(c) supplying a second gas mixture to etch the BARC layer through the reduced dimension opening in patterned photoresist layer; and
(d) supplying a third gas mixture to etch the hardmask layer through an opening formed in the etched BARC layer until the underlying dielectric layer is exposed, wherein the third gas mixture etches the hardmask layer while forming a polymer layer on the hardmask layer.

19. The method of claim 18, wherein (b), (c) and (d) are performed in the etch chamber.

20. An etch chamber coupled to a controller, the controller interfaced with computer readable media, that when executed by the controller, cause a process to be performed in the etch chamber, the process comprising:
depositing a polymer on a patterned photoresist layer such that openings through the photoresist layer are reduced in dimension;
etching an opening in a BARC layer through the reduced dimension opening; and
etching a hardmask layer to expose a dielectric layer through the opening in the BARC layer.

21. An etch chamber coupled to a controller, the controller interfaced with computer readable media, that when executed by the controller, cause a process to be performed in the etch chamber, the process comprising:
supplying a gas mixture including a C₄F₆ gas and a CF₄ gas, wherein C₄F₆ gas deposits a polymer on a patterned photoresist layer such that openings through the photoresist layer are reduced in dimension, while CF₄ gas etches an opening in a BARC layer and a hardmask layer through the reduced dimension opening until an underlying dielectric layer is exposed.
